(19) United States
(12) Patent Application Publication
(10) Pub. No.: US 2010/0084661 A1
(43) Pub. Date: Apr. 8, 2010

(54) DISPLAY SUBSTRATE, METHOD OF MANUFACTURING THE SAME, AND DISPLAY APPARATUS HAVING THE SAME

(75) Inventor: Tae-Hyung HWANG, Seoul (KR)

Correspondence Address: H.C. PARK & ASSOCIATES, PLC, 8500 LEESBURG PIKE, SUITE 7500, VIENNA, VA, 22182, US

(73) Assignee: Samsung Electronics Co., Ltd., Suwon-si (KR)

(21) Appl. No.: 12/405,564

(22) Filed: Mar. 17, 2009

(30) Foreign Application Priority Data
Oct. 7, 2008 (KR) 2008-98210

(51) Int. Cl. H01L 33/00; H01L 21/336

(52) U.S. Cl. 257/72; 438/34; 438/158; 438/694; 257/E33.053; 257/E21.414

(57) ABSTRACT

The present invention relates to a display substrate in which sound devices serving as speakers or a microphones are built, and the display substrate includes a substrate including a sound processing area and a display area, a plurality of sound devices arranged in the sound processing area, and a plurality of pixels arranged in the display area. The sound devices may be formed on the substrate together with the pixels using a same manufacturing process as that used to form the pixels.

### CROSS REFERENCE TO RELATED APPLICATION

This application claims priority from and the benefit of Korean Patent Application No. 2008-98210, filed on Oct. 7, 2008, which is hereby incorporated by reference for all purposes as if fully set forth herein.

### BACKGROUND OF THE INVENTION

1. Field of the Invention

The present invention relates to a display substrate having a sound device, a method of manufacturing the display substrate, and a display apparatus having the display substrate.

2. Discussion of the Background

A display apparatus may be included as part of various electric appliances, such as a computer monitor, a TV, a mobile phone, a notebook computer, and so forth, to display images corresponding to data processed in the electric appliances.

Recently, research has been carried out to improve the portability of portable-data processing devices, and Micro Electro Mechanical Systems (MEMS) have been the subject of steadily increasing attention in this area. MEMS are devices that include a substrate on which micro-scale electrical and/or mechanical components, such as a sensor or an actuator, are integrated. MEMS may be suitable to improve the portability of portable-data processing devices, and MEMS may also be manufactured using known techniques for manufacturing semiconductors or liquid crystal displays (LCDs).

### SUMMARY OF THE INVENTION

The present invention provides a method of manufacturing a display substrate including a sound device therein.

The present invention also provides a display substrate including a sound device therein.

The present invention also provides a display apparatus including the display substrate.

The present invention also provides a sound device that serves as a speaker or a microphone and that may be formed together with display pixels. Thus, the display substrate in which the sound device is built may be easily formed, thereby simplifying the manufacturing method of the display substrate in which the sound device is built.

Additional features of the invention will be set forth in the description which follows, and in part will be apparent from the description, or may be learned by practice of the invention.

The present invention discloses a method of manufacturing a display substrate. A bottom electrode and a first are formed in a sound processing area of a substrate, the bottom electrode being spaced apart from the first electrode, and a gate electrode is formed in a display area of the substrate. A first insulating layer, a second insulating layer, and a semiconductor layer are sequentially formed on the substrate to cover the bottom electrode, the first electrode, and the gate electrode. A first mask pattern is formed on the semiconductor layer, and the semiconductor layer is etched using the first mask pattern as an etch mask to form a preliminary semiconductor pattern. The first mask pattern is then etched to form a second mask pattern, the preliminary semiconductor layer is etched using the second mask pattern as an etch mask to form a semiconductor pattern, and an exposed portion of the second insulating layer is etched together with the preliminary semiconductor pattern to form a second insulating layer pattern. A second electrode is formed on the first electrode in the sound processing area, and a source electrode and a drain electrode, which is spaced apart from the source electrode, is formed on the semiconductor pattern in the display area. A third insulating layer is formed on the substrate to cover the second electrode, the source electrode, and the drain electrode. The third insulating layer is etched to form a third insulating layer pattern so that the first insulating layer and the drain electrode are partially exposed in the sound processing area and the display area, respectively. The exposed first insulating layer is etched to form a first insulating layer pattern and form an undercut under the second electrode. A pixel electrode is formed, the pixel electrode being connected to the drain electrode.

The present invention also discloses a display substrate including a substrate including a display area and a sound processing area, a plurality of pixels arranged in the display area, and a plurality of sound devices arranged in the sound processing area.

The present invention also discloses a display apparatus including a display substrate and an opposite substrate facing the display substrate. The opposite substrate includes a first opposite substrate covering a sound processing area of the display substrate and a second opposite substrate covering a display area of the display substrate.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a perspective view showing an LCD according to an exemplary embodiment of the present invention.

FIG. 2 is a sectional view taken along line I-I′ of FIG. 1.

FIG. 3 is a plan view showing a display area and a sound processing area of a display substrate of FIG. 2.

FIG. 4A is a sectional view taken along line II-II′ of FIG. 3.

FIG. 4B is a sectional view taken along line III-III′ of FIG. 3.

FIG. 5, FIG. 6, FIG. 7, FIG. 8, FIG. 9, FIG. 10, FIG. 11, FIG. 12, and FIG. 13 are views showing a method of manufacturing a liquid crystal display according to an exemplary embodiment of the present invention.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as shown in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments of the present invention will be explained in detail with reference to the accompanying drawings.

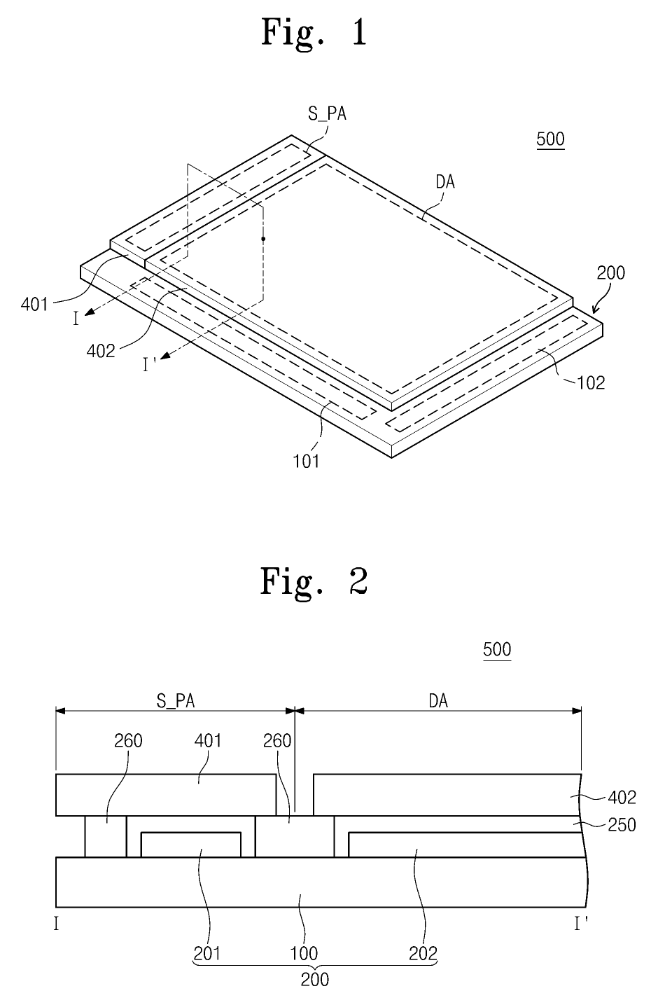

FIG. 1 is a perspective view showing an LCD according to an exemplary embodiment of the present invention, and FIG. 2 is a sectional view taken along line I-I′ of FIG.

Referring to FIG. 1 and FIG. 2, a liquid crystal display 500 includes a display substrate 200, a first opposite substrate 401, a second opposite substrate 402, a liquid crystal layer 250, and a coupling member 260.

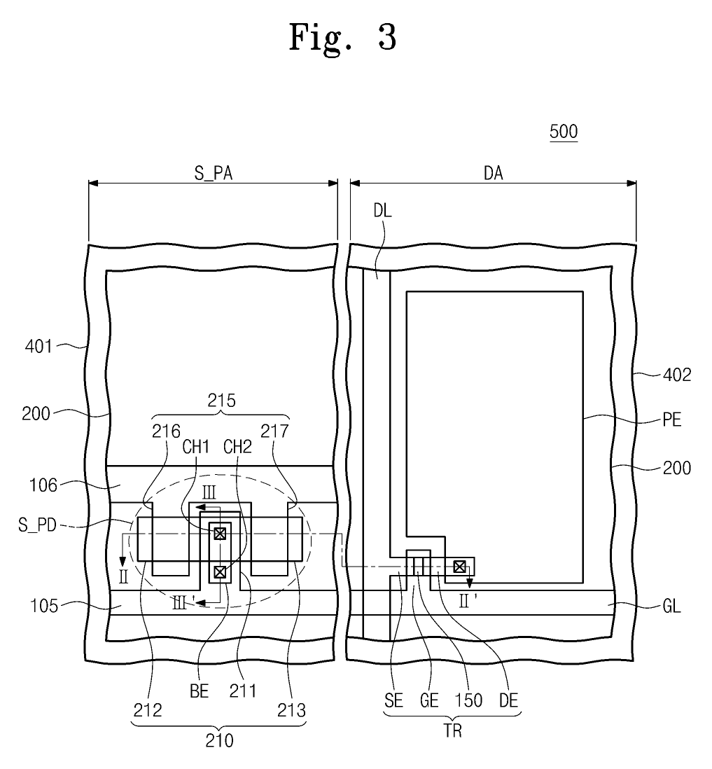

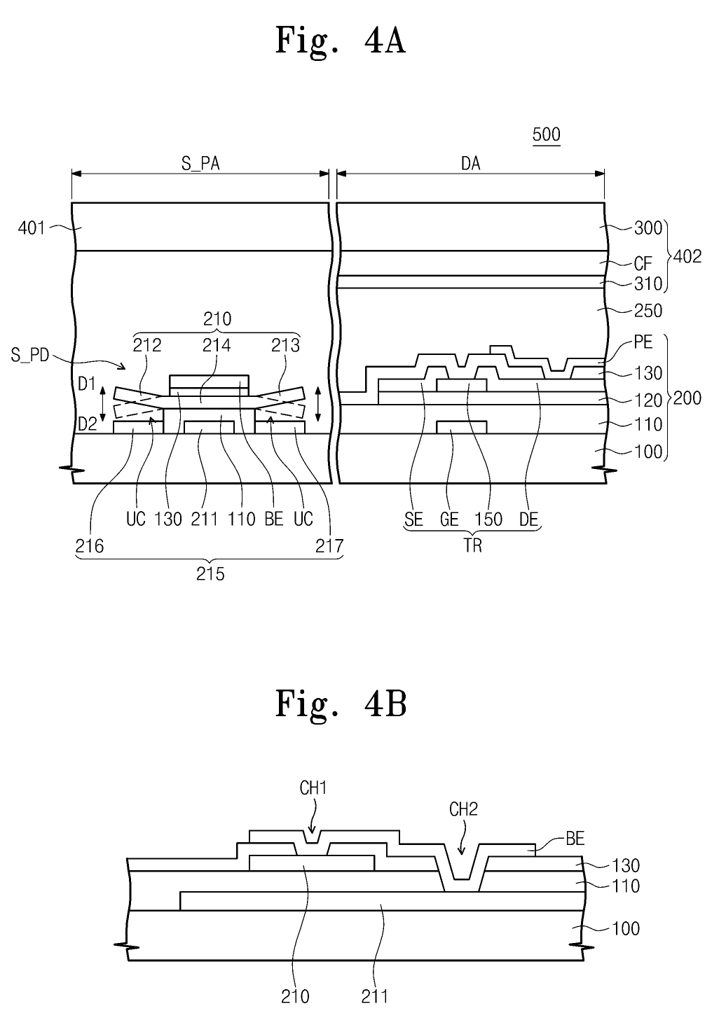

The display substrate 200 includes a first substrate 100, a sound processing part 201, and a pixel part 202. The first substrate 100 may be a glass substrate that has a plate-like shape, and the first substrate 100 includes a display area DA and a sound processing area S_PA spaced apart from the display area DA. The sound processing part 201 is arranged in the sound processing area S_PA, and the sound processing part 201 includes a plurality of sound devices. Each of the sound devices may serve as a micro-speaker that outputs an electric signal as sound. More detailed descriptions about the structure and function of the sound devices will be described below with reference to FIG. 3 and FIG. 4A.

The pixel part 202 is arranged in the display area DA. The pixel part 202 includes a plurality of thin film transistors (TFTs) and pixel electrodes. The TFTs are electrically connected to the pixel electrodes in one-to-one correspondence. Although not shown in FIG. 1 and FIG. 2, the display substrate 200 is connected to a data driver in a data bonding part 101 and connected to a gate driver in a gate bonding part 102, and the display substrate 200 controls an operation of the pixel part 202 using a data signal applied from the data driver and a gate signal applied from the gate driver.

The first and second opposite substrates 401 and 402 are arranged to face the display substrate 200 and coupled with the display substrate 200 by a coupling member 260. The first opposite substrate 401 is coupled with a portion of the display substrate 200 corresponding to the sound processing area S_PA, and the second opposite substrate 402 is coupled with a portion of the display substrate 200 corresponding to the display area DA. The liquid crystal layer 250 is disposed between the portion of the display substrate 200 corresponding to the display area DA and the second opposite substrate 402.

Since each base substrate of the first and second opposite substrates 401 and 402 includes different materials from each other, the display substrate 200 is coupled with the first opposite substrate 401 in the sound processing area S_PA and the second opposite substrate 402 in the display area DA. A second substrate 300 (shown in FIG. 4) for the base substrate of the second opposite substrate 402 may be made of a glass material, and the first opposite substrate 401 may include a plastic material that is less dense than glass material to transmit sound generated from the sound processing part 201 to the exterior of the LCD.

The first opposite substrate 401 may have a porous-shaped body in order to easily transmit the sound generated from the sound processing part 201 to the exterior. Also, unlike the exemplary embodiment in FIG. 1 and FIG. 2, the first and second opposite substrates 401 and 402 may be formed integrally with each other using plastic or glass, and then coupled with the display substrate 200.

FIG. 3 is a plan view showing a display area and a sound processing area of a display substrate of FIG. 2. FIG. 4A is a sectional view taken along line II-II′ of FIG. 3. FIG. 4B is a sectional view taken along line III-III′ of FIG. 3. In detail, a sound device S_PD included in the sound processing part 201 (shown in FIG. 2) and arranged in the sound processing area S_PA, and the thin film transistor TR and the pixel electrode PE included in the pixel part 202 (shown in FIG. 2) and arranged in the display area DA are shown in FIG. 3. The sound processing part 201 includes a plurality of sound devices. However, the sound devices have the same structure and function. Thus, only one sound device will be shown and others will be omitted. As well, the pixel part 202 includes a plurality of TFTs and a plurality of pixel electrodes, but the TFTs have the same structure and function and the pixel electrodes have the same structure and function. Thus, only one TFT and one pixel electrode will be shown in FIG. 3, and others will be omitted.

Referring to FIG. 3, FIG. 4A, and FIG. 4B, the sound device S_PD is arranged on the first substrate 100 corresponding to the sound processing area S_PA, and the thin film transistor TR and the pixel electrode PE electrically connected to the thin film transistor TR are arranged on the first substrate 100 corresponding to the display area DA.

The sound device S_PD includes a bottom electrode 211, a first electrode 215, and a second electrode 210. The first electrode 215 includes a first sub-electrode 216 and a second sub-electrode 217. The bottom electrode 211 branches from a first signal line 105 and is arranged on the first substrate 100.

The first and second sub-electrodes 216 and 217 are arranged on the first substrate 100 and spaced apart from the bottom electrode 211. Also, each of the first and second sub-electrodes 216 and 217 branches from a second signal line 106.

A first insulating layer pattern 110 is arranged on the first substrate 100 corresponding to the sound processing area S_PA to cover the bottom electrode 211. The first insulating layer pattern 110 includes an insulating material, such as silicon nitride (SiNx), and covers the bottom electrode 211. Portions of the first insulating layer pattern 110, which correspond to upper portions of the first and second sub-electrodes 216 and 217, are removed to form an undercut part UC. That is, as shown in FIG. 4A, although the bottom electrode 211, the first sub-electrode 216, and the second sub-electrode 217 are arranged adjacent to each other, only the bottom electrode 211 is covered by the first insulating layer pattern 110, and the first and second sub-electrodes 216 and 217 are exposed to an exterior through the undercut part UC.

The second electrode 210 is arranged on the first insulating layer pattern 110. The second electrode 210 includes a first vibrating part 212, a second vibrating part 213, and a fixing part 214. The fixing part 214 is fixed onto the first insulating layer pattern 110, and the first vibrating part 212 extends from the fixing part 214 to face the first sub-electrode 216. In addition, the second vibrating part 213 extends from the fixing part 214 in an opposite direction to the first vibrating part 212 to face the second sub-electrode 217.

A third insulating layer pattern 130 is arranged on the fixing part 214, and a connection electrode BE is arranged on the third insulating layer pattern 130. The connection electrode BE is electrically connected to the second electrode 210 and the bottom electrode 211 through a first contact hole CH1 and a second contact hole CH2, respectively, to electrically connect the second electrode 210 to the bottom electrode 211. Thus, the second electrode 210 may receive an electric signal from the first signal line 105 via the bottom electrode 211, which protrudes from the first signal line 105.

As described above, since the undercut part UC is formed under the first vibrating part 212 and the second vibrating part 213, the first vibrating part 212 and the second vibrating part 213 face the first sub-electrode 216 and the second sub-electrode 217, respectively, with spaces respectively interposed therebetween. Also, the second electrode 210 includes a metal material and has a thin film shape, and the fixing part 214 is fixed onto the first insulating layer pattern 110. Therefore, an attractive force or a repulsive force occurs between the first electrode 215 and the second electrode 210 according to a charge state of the first and second electrodes 215 and 210, so that the first and second vibrating parts 212 and 213 may vibrate in a first direction D1 or a second direction D2.

For instance, when the first sub-electrode 216 and the first vibrating part 212 are charged with a positive charge, a repulsive force occurs between the first sub-electrode 216 and the first vibrating part 212, so that the first vibrating part 212 vibrates in the first direction DI by the repulsive force. On the contrary, when the first sub-electrode 216 and the first vibrating part 212 are charged with an opposite charge from each other, since the attractive force occurs between the first sub-electrode 216 and the first vibrating part 212, the first vibrating part 212 vibrates in the second direction D2.

In addition, the second vibrating part 213 is electrically connected to the first vibrating part 212, and the second sub-electrode 217 is electrically connected to the first sub-electrode 216. Thus, when the first vibrating part 212 vibrates in the first direction D1 or the second direction D2, the second vibrating part 213 vibrates in the same direction along with the first vibrating part 212.

As described above, when the first and second vibrating parts 212 and 213 sequentially vibrate in the first direction D1 or the second direction D2 by the electric signals applied from the first and second signal lines 105 and 106 and a pulse width of the electric signals is modulated to control the number of vibrations of the first and second vibrating parts 212 and 213, the first and second vibrating parts 212 and 213 may serve as a diaphragm of a speaker system to generate sound waves with a desired wave number.

In the present exemplary embodiment, the sound device S_PD has a speaker function. Alternatively, in another exemplary embodiment of the present invention, the sound device S_PD may serve as a microphone that converts a received sound into an electric signal. When the sound device S_PD serves as the microphone, the sound device S_PD may be driven as a condenser type microphone. The sound device S_PD may generate the electric signals when the first and second vibrating parts 212 and 213 vibrate according to sound received from the exterior to change the capacitance of a condenser having the first and second electrodes 215 and 210.

In another portion of the device, the thin film transistor TR and the pixel electrode PE, which is electrically connected to the thin film transistor TR, are arranged on the first substrate 100 corresponding to the display area DA.

The thin film transistor TR includes a gate electrode GE, a source electrode SE, a semiconductor pattern 150, and a drain electrode DE. The gate electrode GE branches from a gate line GL and is arranged on the first substrate 100. Also, the first insulating layer pattern 110 is arranged on the gate electrode GE to cover the gate electrode GE, and a second insulating layer pattern 120 is arranged on the first insulating layer pattern 110. The semiconductor pattern 150 is arranged on the second insulating layer pattern 120, and the source electrode SE and the drain electrode DE, which is spaced apart from the source electrode SE, are arranged on the semiconductor pattern 150.

The third insulating layer pattern 130 is arranged on the thin film transistor TR to cover the thin film transistor TR. Also, the pixel electrode PE is arranged on the third insulating layer pattern 130 to be electrically connected to the drain electrode DE through an opening formed through the third insulating layer pattern 130.

As described above, the first insulating layer pattern 110 covers the bottom electrode 211 in the sound processing area S_PA, and the first insulating layer pattern 110 covers the gate electrode GE in the display area DA. In addition, the third insulating layer pattern 130 covers the fixing part 214 in the sound processing area S_PA, and the third insulating layer pattern 130 covers the thin film transistor TR in the display area DA. That is, each of the first and third insulating layer patterns 110 and 130 is patterned to have a different shape in the sound processing area S_PA and the display area DA.

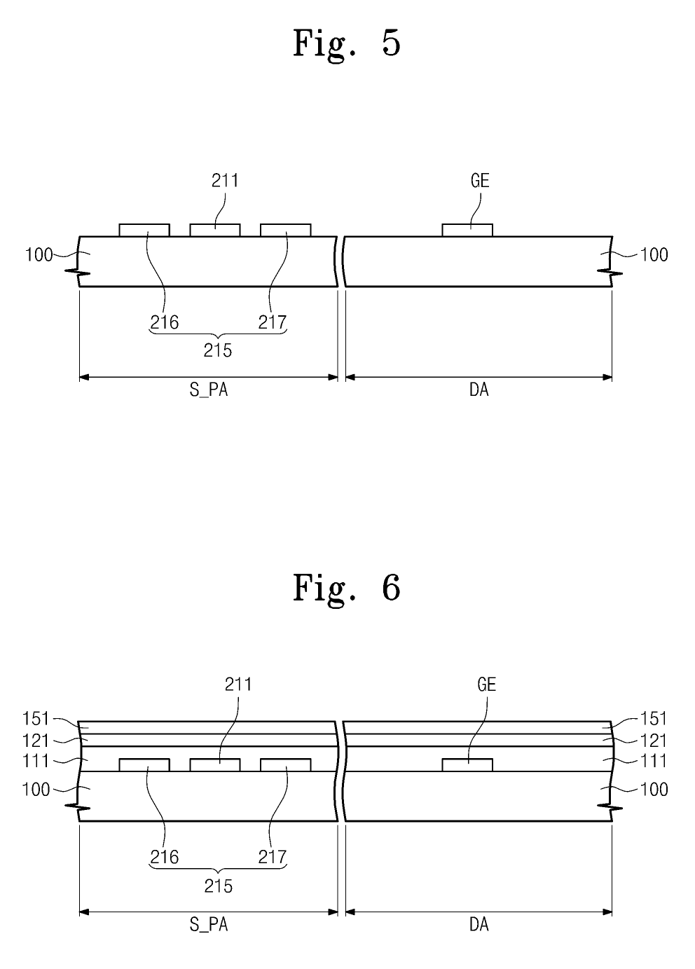

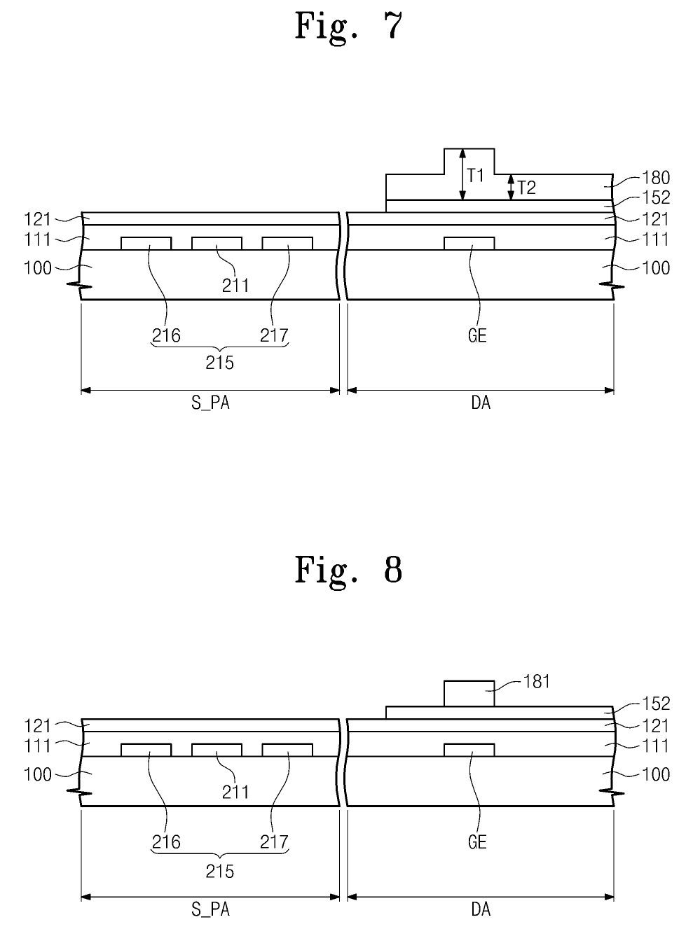

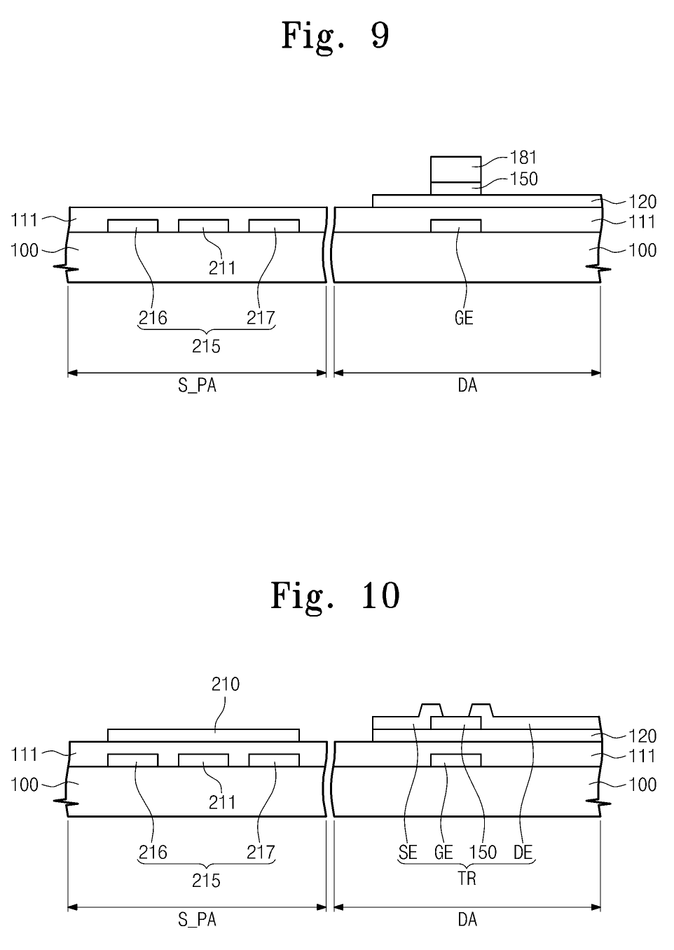

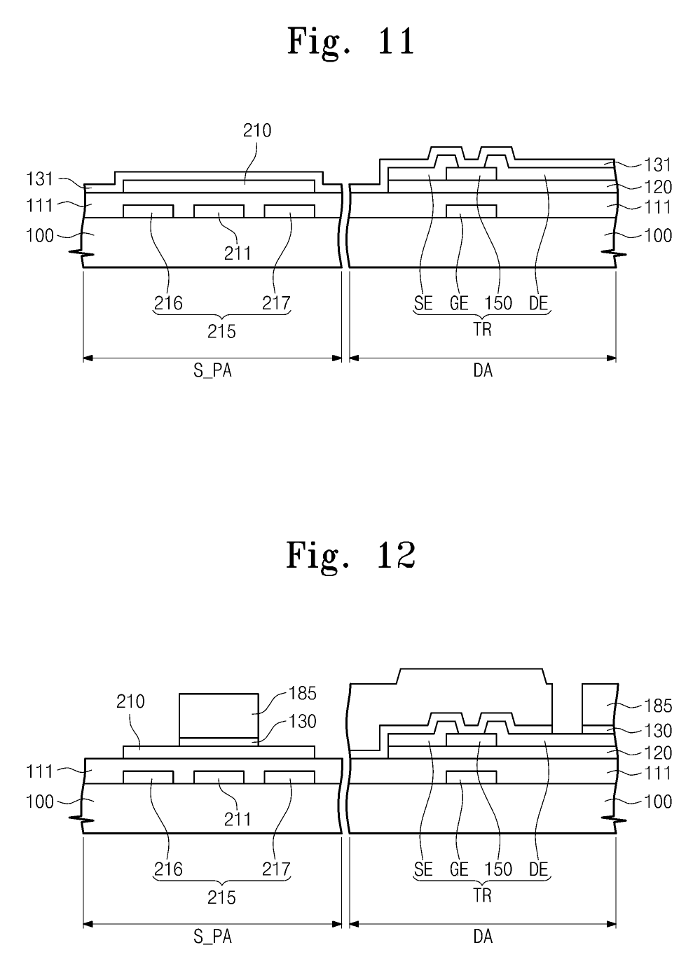

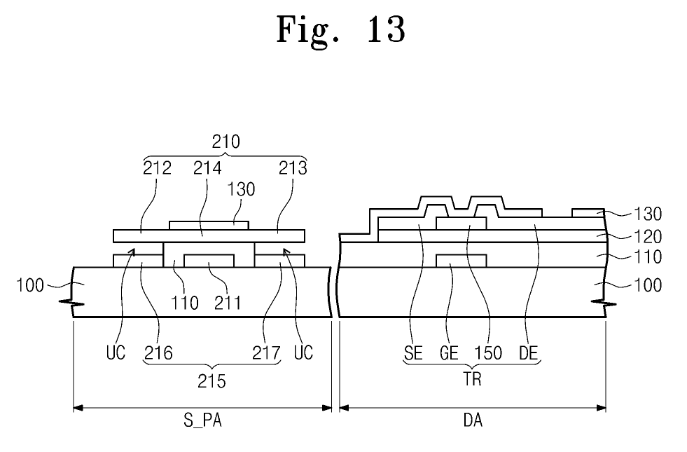

The shape of the first and third insulating layer patterns 110 and 130 in the sound processing area S_PA is related to an operation of the sound device S_PD, and more particularly, the first and third insulating layer patterns 110 and 130 are removed such that the first and second vibrating parts 212 and 213 may vibrate in two different directions, for example, the first and second directions D1 and D2. The more detailed descriptions about a manufacturing process of the first and third insulating layer patterns 110 and 130 having a different shape in different areas will be described with reference to FIG. 5, FIG. 6, FIG. 7, FIG. 8, FIG. 9, FIG. 10, FIG. 11, FIG. 12, and FIG. 13.

The second insulating layer pattern 120 is arranged on the first insulating layer pattern 110 in the display area DA and is completely removed in the sound processing area S_PA. In detail, the second insulating layer pattern 120 is arranged in an area in which the thin film transistor TR is formed, in the display area DA. The second insulating layer 120 is arranged to cover the first insulating layer pattern 110 in an area where the thin film transistor TR is formed.

The display substrate 200 is coupled with the first opposite substrate 401 in the sound processing area S_PA and coupled with the second opposite substrate 402 in the display area DA. The first opposite substrate 401 may be a plastic substrate that covers the sound device S_PD. The second opposite substrate 402 includes the second substrate 300, a color filter CF, and a common electrode 310. The second substrate 300 may be a glass substrate that serves as the base substrate of the second opposite substrate 402, and the color filter CF is arranged on the second substrate 300 to filter a white light passing through the color filter CF into a predetermined color. The common electrode 310 is arranged on the color filter CF and forms an electric field in cooperation with the pixel electrode PE to control the degree of twist of the liquid crystals of the liquid crystal layer 250 by the electric field.

FIG. 5, FIG. 6, FIG. 7, FIG. 8, FIG. 9, FIG. 10, FIG. 11, FIG. 12, and FIG. 13 are views showing a method of manufacturing a liquid crystal display according to an exemplary embodiment of the present invention. In FIG. 5, FIG. 6, FIG. 7, FIG. 8, FIG. 9, FIG. 10, FIG. 11, FIG. 12, and FIG. 13, the same reference numerals denote the same elements in FIG. 1, FIG. 2, FIG. 3, FIG. 4A, and FIG. 4B, and thus detailed descriptions of the same elements will be omitted.

Referring to FIG. 5, the bottom electrode 211 and the first electrode 215, which includes the first sub-electrode 216 and the second sub-electrode 217, are formed in the sound processing area S_PA of the first substrate 100, and the gate electrode GE is formed in the display area DA of the first substrate 100. Although not shown in detail in FIGS. 5, a conductive layer is formed on an entire surface of the first substrate 100, and the conductive layer is patterned to simultaneously form the bottom electrode 211, the first electrode 215, and the gate electrode GE.

Referring to FIG. 6, a first insulating layer 111, a second insulating layer 121, and a semiconductor layer 151 are sequentially formed by a chemical vapor deposition (CVD) process to cover the bottom electrode 211, the first electrode 215, and the gate electrode GE.

In the exemplary embodiment of the present invention, each of the first and second insulating layers 111 and 121 includes silicon nitride. However, process conditions of the CVD for the first insulating layer 111 may be different from those of the second insulating layer 121, and the first insulating layer 111 may be deposited at a rate of deposition faster than that of the second insulating layer 121. For instance, when forming the first and second insulating layers 111 and 121 using a first chamber (not shown) and a second chamber (not shown), respectively, a flow amount of reaction gas in the first chamber may be larger than that of the second chamber, and thus, an inner pressure of the first chamber may be larger than that of the second chamber. Thus, a function group of the reaction gas used in the CVD process may be present in greater amounts in the first chamber than the second chamber, and the first insulating layer 111 may therefore be deposited faster than the second insulating layer 121.

In a case that the second insulating layer 121 is deposited slower than the first insulating layer 111, molecules deposited on a surface of the second insulating layer 121 may easily fill in defects formed on the surface of the second insulating layer 121. However, it may be difficult for molecules deposited on a surface of the first insulating layer 111 to fill in defects formed on the surface of the first insulating layer 111. Therefore, the molecules in the second insulating layer 121 may be more densely arranged than the molecules in the first insulating layer 111. Thus, although the first and second insulating layer 111 and 121 include the same material, since the molecules in the second insulating layer 121 may be more densely arranged than the molecules in the first insulating layer 111, the second insulating layer 121 may be etched more slowly than the first insulating layer 111 with respect to a certain etchant.

In another exemplary embodiment of the present invention, the first insulating layer 111 and the second insulating layer 121 may include silicon oxide (SiOx). In a case that the first and second insulating layers 111 and 121 include silicon oxide, the deposition speed of the first and second insulating layers 111 and 121 may be controlled to be different from each other so that the first insulating layer 111 may be etched faster than the second insulating layer 121 with respect to an etchant, such as sulfur hexafluoride (SF₆) or carbon tetrafluoride (CF₄).

Referring to FIG. 7 and FIG. 8, after forming the semiconductor layer 151 (shown in FIG. 6), a first mask pattern 180 is formed on the semiconductor layer 151. The first mask pattern 180 has different thicknesses in different regions thereof. More particularly, the first mask pattern 180 has a first thickness T1 corresponding to a channel area of the thin film transistor TR (shown in FIG. 10) and has a second thickness T2 thinner than the first thickness T1 corresponding to an area where the thin film transistor TR is formed except for the channel area.

After forming the first mask pattern 180, the semiconductor layer 151 is patterned using the first mask pattern 180 to form a preliminary semiconductor pattern 152. After forming the preliminary semiconductor pattern 152, the first mask pattern 180 is etched by the second thickness T2 (shown in FIG. 7) to form a second mask pattern 181. Thus, the preliminary semiconductor pattern 152 is exposed to an exterior except the channel area of the thin film transistor TR (shown in FIG. 10).

Referring to FIG. 8 and FIG. 9, the second insulating layer 121 and the preliminary semiconductor pattern 152 are etched using the second mask pattern 181 as a mask. Then, the exposed portion of the preliminary semiconductor pattern 152 and the exposed portion of the second insulating layer 121 are removed to respectively form the semiconductor pattern 150 and the second insulating layer pattern 120. During the etching process, the second insulating layer 121 is removed in the sound processing area S_PA to expose the first insulating layer 111 to the exterior, and the exposed portion of the preliminary semiconductor pattern 152 and the exposed portion of the second insulating layer 121 are removed in the display area DA.

Thus, the etchant used for the etching process may include a material that etches both the second insulating layer 121 and the preliminary semiconductor pattern 152, such as sulfur hexafluoride (SF₆) or carbon tetrafluoride (CF₄).

Here, the exposed portion of the preliminary semiconductor pattern 152 and the exposed portion of the second insulating layer 121 should be completely removed through the etching process. Therefore, it is desirable to decide a thickness of the second insulating layer 121 and a thickness of the preliminary semiconductor pattern 152 in consideration of the etch selectivity of the second insulating layer 121 and the preliminary semiconductor pattern 152 with respect to the etchant. For instance, when the second insulating layer 121 is etched twice as fast as the preliminary semiconductor pattern 152 with respect to the etchant, the thickness of the second insulating layer 121 should be twice that of the preliminary semiconductor pattern 152.

Referring to FIG. 10, the second mask pattern 181 is removed, and the second electrode 210, the source electrode SE, and the drain electrode DE are formed. Although not shown in FIG. 10, a conductive layer is deposited on the first substrate 100, and the conductive layer is patterned, so that the second electrode SE, the source electrode, and the drain electrode DE are substantially simultaneously formed.

Referring to FIG. 11 and FIG. 12, a third insulating layer 131 is formed on the first substrate 100 to cover the second electrode 210, the source electrode SE, and the drain electrode DE, and a third mask pattern 185 is formed on the third insulating layer 131. The third mask pattern 185 faces the bottom electrode 211 while interposing the first insulating layer 111 therebetween in the sound processing area S_PA, and the third mask pattern 185 has an opening in the display area DA to partially expose the drain electrode DE.

The third insulating layer 131 includes a material that is etched more slowly than the first insulating layer 111 with respect to a certain etchant. Thus, the first insulating layer 111 and the third insulating layer 131 may include different materials from each other to have an etch selectivity with respect to the etchant. Alternatively, the third insulating layer 131 and the first insulating layer 111 may include the same material. When the third insulating layer 131 and the first insulating layer 111 include the same material, the third insulting layer 131 may be formed by depositing the material slower than when the first insulating layer 111 is formed. By depositing the third insulating layer 131 more slowly than the first insulating layer 111, the third insulating layer 131 may be formed more densely than the first insulating layer 111. Thus, the third insulating layer 131 may be etched more slowly than the first insulating layer 111.

After forming the third mask pattern 185, the third insulating layer 131 is patterned using the third mask pattern 185 as a mask to form the third insulating layer pattern 130.

Referring to FIG. 13, during the etching process of the first insulating layer 111, the first insulating layer 111 corresponding to the sound processing area S_PA is partially removed to form the first insulating layer pattern 110. More particularly, the exposed portion of the first insulating layer 111 is removed to form an undercut part UC under the first and second vibrating parts 212 and 213 in the sound processing area S_PA. Thus, a space is formed between the first vibrating part 212 and the first sub-electrode 216 and between the second vibrating part 213 and the second sub-electrode 217.

During the etching process, since the first insulating layer 111 corresponding to the display area DA is covered by the second and the third insulating layer patterns 120 and 130, the first insulating layer 111 corresponding to the display area DA is prevented from being etched. Thus, the undercut part UC formed in the sound processing area S_PA is not formed in the display area DA.

Referring again to FIG. 4A, the connection electrode BE is formed on the third insulating layer 130 in the sound processing area S_PA, and the pixel electrode PE electrically connected to the drain electrode DE is formed in the display area DA. Although not shown in FIG. 4A, in order to form the connection electrode BE and the pixel electrode PE, a transparent conductive layer, which may include a transparent conductive material such as indium tin oxide (ITO) and indium zinc oxide (IZO), is formed on the first substrate 100, and the transparent conductive layer is patterned to simultaneously form the connection electrode BE and the pixel electrode PE. As described above with reference to FIG. 4B, the connection electrode BE electrically connects the bottom electrode 211 to the second electrode 210.

According to the above, the sound device that serves as a speaker or a microphone may be formed together with display pixels. Thus, the display substrate in which the sound device is built may be easily formed, thereby simplifying the manufacturing method of the display substrate in which the sound device is built.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A method of manufacturing a display substrate, the method comprising:
forming a bottom electrode and a first electrode in a sound processing area of a substrate, the bottom electrode being spaced apart from the first electrode;
forming a gate electrode in a display area of the substrate;
sequentially forming a first insulating layer, a second insulating layer, and a semiconductor layer on the substrate to cover the bottom electrode, the first electrode, and the gate electrode;
forming a first mask pattern on the semiconductor layer;
etching the semiconductor layer using the first mask pattern as an etch mask to form a preliminary semiconductor pattern;
etching the first mask pattern to form a second mask pattern;
etching the preliminary semiconductor layer using the second mask pattern as an etch mask to form a semiconductor pattern, and etching an exposed portion of the second insulating layer together with the preliminary semiconductor pattern to form a second insulating layer pattern;
forming a second electrode on the first electrode in the sound processing area, and forming a source electrode and a drain electrode, which is spaced apart from the source electrode, on the semiconductor pattern in the display area;
forming a third insulating layer on the substrate to cover the second electrode, the source electrode, and the drain electrode;
etching the third insulating layer to form a third insulating layer pattern so that the first insulating layer and the drain electrode are partially exposed in the sound processing area and the display area, respectively;
etching the exposed first insulating layer to form a first insulating layer pattern and form an undercut under the second electrode; and
forming a pixel electrode connected to the drain electrode.

2. The method of claim 1, wherein the first insulating layer has a higher etch selectivity than those of the second insulating layer and the third insulating layer with respect to the same etchant.

3. The method of claim 2, wherein the first insulating layer, the second insulating layer, and the third insulating layer comprise the same material, and the material is deposited at a faster speed when forming the first insulating layer than the speed at which the material is deposited when forming the second insulating layer and the third insulating layer.

4. The method of claim 3, wherein the first insulating layer, the second insulating layer, and the third insulating layer comprise silicon nitride.

5. The method of claim 1, wherein the first mask pattern comprises a first thickness in a first area and a second thickness thicker than the first thickness in a second area, and the second mask pattern is formed by thinning the first mask pattern by the first thickness.

6. The method of claim 5, wherein the second area corresponds to a channel area of a thin film transistor comprising the semiconductor pattern, and the first area corresponds to an area where the thin film transistor is formed except for the second area.

7. The method of claim 6, wherein the second insulating layer pattern is arranged on the first insulating layer pattern in the area where the thin film transistor is formed.

8. The method of claim 1, wherein at least one end portion of the second electrode is spaced apart from the first electrode, a space is formed between the second electrode and the first electrode, and the space is defined by the undercut.

9. The method of claim 1, further comprising:
forming a first signal line connected to the bottom electrode; and
forming a second signal line spaced apart from the first signal line and connected to the first electrode.

10. The method of claim 9, wherein an attractive force or a repulsive force occurs between the first electrode and the second electrode by electric signals applied from the first signal line and the second signal line, and the second electrode is vibrated by the attractive force or the repulsive force.

11. A display substrate, comprising:
a substrate comprising a display area and a sound processing area;
a plurality of pixels arranged in the display area; and
a plurality of sound devices arranged in the sound processing area,
wherein each sound device comprises:
a bottom electrode arranged on the substrate;
a first electrode arranged on the substrate and spaced apart from the bottom electrode;
a first insulating layer pattern arranged on the bottom electrode; and
a second electrode arranged on the first insulating layer pattern and connected to the bottom electrode, at least one end portion of the second electrode being spaced apart from the first electrode with an empty space disposed between the at least one end portion of the second electrode and the first electrode.

12. The display substrate of claim 11, wherein each pixel comprises:
a thin film transistor; and
a pixel electrode connected to the thin film transistor, and wherein
the first insulating layer pattern is arranged on an electrode in the display area, the electrode being arranged closest to the substrate among electrodes comprising the thin film transistor.

13. The display substrate of claim 12, further comprising:
a first signal line arranged on the substrate and connected to the bottom electrode;
a second signal line arranged on the substrate and spaced apart from the first signal line, the second signal line being connected to the first electrode;
a second insulating layer pattern arranged on the first insulating layer pattern in an area where the thin film transistor is formed;
a third insulating layer pattern arranged on the second electrode in the sound processing area, the third insulating layer pattern comprising a first contact hole and a second contact hole corresponding to the second electrode and the bottom electrode, respectively, the first contact hole and the second contact hole being formed in the third insulating layer; and
a connection electrode arranged on the third insulating layer pattern to connect the second electrode to the bottom electrode through the first contact hole and the second contact hole.

14. The display substrate of claim 11, wherein the second electrode comprises:
a fixing part overlapping with the first insulating layer pattern, the fixing part contacting the first insulating layer pattern; and
at least one vibrating part extending from the fixing part to face the first electrode, the empty space being disposed between the at least one vibrating part and the first electrode, the vibrating part being vibrated by an attractive force or a repulsive force occurring between the first electrode and the vibrating part.

15. The display substrate of claim 14, wherein the first insulating layer pattern is removed corresponding to the empty space disposed between the vibrating part and the first electrode.

16. A display apparatus, comprising:
a substrate comprising a display area and a sound processing area;
an opposite substrate facing the substrate;
a plurality of pixels arranged in the display area; and
a plurality of sound devices arranged in the sound processing area,
wherein each sound device comprises:
a bottom electrode arranged on the substrate;
a first electrode arranged on the substrate and spaced apart from the bottom electrode;
a first insulating layer pattern arranged on the bottom electrode; and
a second electrode arranged on the first insulating layer pattern and electrically connected to the bottom electrode, at least one end portion of the second electrode being spaced apart from the first electrode with an empty space disposed between the at least one end portion of the second electrode and the first electrode.

17. The display apparatus of claim 16, wherein each pixel comprises:
a thin film transistor; and
a pixel electrode connected to the thin film transistor, wherein
the first insulating layer pattern is arranged on an electrode in the display area, the electrode being arranged closest to the substrate among electrodes comprising the thin film transistor,.

18. The display apparatus of claim 17, further comprising:
a first signal line arranged on the substrate and connected to the bottom electrode;
a second signal line arranged on the substrate and spaced apart from the first signal line, the second signal line being connected to the first electrode;
a second insulating layer pattern arranged on the first insulating layer pattern in an area where the thin film transistor is formed;
a third insulating layer pattern arranged on the second electrode in the sound processing area, the third insulating layer pattern comprising a first contact hole and a second contact hole corresponding to the second electrode and the bottom electrode, respectively, the first contact hole and the second contact hole being formed in the third insulating layer pattern; and
a connection electrode arranged on the third insulating layer pattern to connect the second electrode to the bottom electrode through the first contact hole and the second contact hole.

19. The display apparatus of claim 16, wherein the second electrode comprises:
a fixing part overlapping with the first insulating layer pattern, the fixing part contacting the first insulating layer pattern; and
at least one vibrating part extending from the fixing part to face the first electrode with the empty space disposed between the at least one vibrating part and the first electrode, and the vibrating part being vibrated by an attractive force or a repulsive force occurring between the first electrode and the vibrating part.

20. The display apparatus of claim 16, further comprising a liquid crystal layer disposed between a portion of the substrate and the opposite substrate, the portion corresponding to the display area.
